(19) United States
(12) Patent Application Publication
(10) Pub. No.: US 2023/0335202 A1
(43) Pub. Date: Oct. 19, 2023

(54) NON-VOLATILE MEMORY

(71) Applicant: Rohm Co., Ltd., Kyoto (JP)

(72) Inventor: Seiji TAKENAKA, Kyoto (JP)

(21) Appl. No.: 18/027,268

(22) PCT Filed: Sep. 2, 2021
(86) PCT No.: PCT/JP2021/032241

§ 371 Date: Mar. 20, 2023

(30) Foreign Application Priority Data
Oct. 5, 2020 (JP) 2020-168241

(51) Int. Cl. G11C 16/30; G11C 16/04; G11C 16/10; G11C 16/26

(52) U.S. Cl. CPC G11C 16/30; G11C 16/0441; G11C 16/10; G11C 16/26

(57) ABSTRACT

A memory cell has a first transistor and a second transistor. A drive circuit includes a boost circuit configured to generate a boost voltage on a boost line by boosting a predetermined reference voltage, and an adjustment circuit configured to adjust the boost voltage by drawing from the boost line an adjustment current commensurate with the boost voltage. The drive circuit feeds the adjusted boost voltage as the read voltage to the gates of the first and second transistors. In a read operation in which the read voltage is fed, the signal output circuit outputs a signal associated with a first value or a signal associated with a second value based on the drain currents in the first and second transistors.

### TECHNICAL FIELD

The present disclosure relates to non-volatile memories.

### BACKGROUND ART

Non-volatile memories that exploit hot carrier injection into transistors are known.

A non-volatile memory of this type includes, as memory elements, a first and a second transistor (m1 and m2; not illustrated) with paired characteristics in their initial state, and hot carriers are injected into only one of those transistors to change its characteristics. In a read operation thereafter, based on the magnitude relationship between the drain currents of the first and second transistors observed when they are fed with a common gate voltage (read voltage), whether data corresponding to “0” or data corresponding to “1” is stored in them is read out. For example, a state where the drain current of the first transistor is lower (a state where the characteristics of the first transistor have changed) corresponds to a state where data of “0” is stored, and a state where the drain current of the second transistor is lower (a state where the characteristics of the second transistor have changed) corresponds to a state where data of “1” is stored.

Note that, in the non-volatile memory described above, the stored data (stored value) in the initial state is indefinite. To avoid indefiniteness in the data stored in the initial state, some known non-volatile memories are configured such that a higher current passes through the second transistor in the initial state. In non-volatile memories of this type, the stored data in the initial state can be fixed to be “0”, and it can be turned to “1” through hot carrier injection into the second transistor.

### CITATION LIST

### Patent Literature

Patent Document 1: JP-A-2011-103158

### SUMMARY OF DISCLOSURE

### Technical Problem

Incidentally, the memory elements (m1, m2) in a non-volatile memory have a comparatively high gate threshold voltage. To generate a gate voltage (read voltage) reliably higher than the gate threshold voltage in a read operation, using a charge pump is considered to be expedient. In that case, from the perspectives of circuit size reduction and the like, it is preferable to form the charge pump with a simple configuration; doing so, however, makes it difficult to feed an accurate read voltage to the gates of the memory elements (m1, m2).

In the memory elements (m1, m2), the relationship of the gate-source voltage with the drain current varies greatly with element-to-element variation and temperature variation. Thus, even if the read voltage is constant, the drain current in the memory elements (m1, m2) in a read operation varies in different ways. The drain current in the memory elements (m1, m2) in a read operation varies even more if the read voltage varies.

On the other hand, an excessively high drain current in the memory elements (m1, m2) in a read operation leads to increased power consumption. From the perspective of power saving, it is preferable to reduce the drain current in a read operation. Too low a drain current in them, however, makes it difficult to read the stored data in a limited time. It is therefore preferable, in a read operation, to pass through the memory elements a drain current of an adequate magnitude that does not depend on element-to-element variation or temperature variation (i.e., to limit the range of variation of magnitude of the drain current). If this requirement is met (if the drain current in the memory elements in a read operation can be optimized), power saving is achieved. Moreover, if the drain current in the memory elements (m1, m2) in a read operation varies greatly, a circuit peripheral to it (e.g., a circuit as the source of the current and a switch on the path of the current) need to be configured with consideration given to the maximum value of the drain current as designed, and this increases the size of the peripheral circuit. Here, limiting the range of variation of the magnitude of the drain current permits size reduction in the peripheral circuit. Furthermore, if the drain current in the memory elements (m1, m2) in a read operation varies greatly, this adversely affects the characteristics of the non-volatile memory. Here, limiting the range of variation of the magnitude of the drain current (ideally making it constant) is expected to improve the characteristics of the non-volatile memory.

An object of the present disclosure is to provide a non-volatile memory that contributes to optimizing the drain current in a memory element (transistor) in a read operation.

### Solution to Problem

According to one aspect of what is disclosed herein, a non-volatile memory includes: a memory cell having a first transistor and a second transistor; a drive circuit configured to feed a read voltage to the gates of the first and second transistors; and a signal output circuit configured to output, in a read operation in which the read voltage is fed, a signal associated with a first value or a signal associated with a second value based on the drain currents in the first and second transistors. The drive circuit includes: a boost circuit configured to generate a boost voltage on a boost line by boosting a predetermined reference voltage; and an adjustment circuit configured to adjust the boost voltage by drawing from the boost line an adjustment current commensurate with the boost voltage. The drive circuit is configured to feed, in the read operation, the adjusted boost voltage as the read voltage to the gates of the first and second transistors.

### Advantageous Effects of Disclosure

According to the present disclosure, it is possible to provide a non-volatile memory that contributes to optimizing the drain current in a memory element (transistor) in a read operation.

### BRIEF DESCRIPTION OF DRAWINGS

FIG. 1 is a configuration diagram of a principal part of a storage circuit according to a first embodiment of the present disclosure.

FIG. 2 is a diagram showing the states of voltages in the storage circuit during a pre-charge period according to the first embodiment of the present disclosure.

FIG. 3 is a diagram showing the states of voltages in the storage circuit during a read period according to the first embodiment of the present disclosure.

FIG. 4A is a diagram showing the drain voltages of transistors in the pre-charge and read periods according to the first embodiment of the present disclosure.

FIG. 4B is a diagram showing the drain voltages of transistors in the pre-charge and read periods according to the first embodiment of the present disclosure.

FIG. 5A is a diagram showing the states of voltages in the storage circuit during a first program operation according to the first embodiment of the present disclosure.

FIG. 5B is a diagram showing the states of voltages in the storage circuit during a second program operation according to the first embodiment of the present disclosure.

FIG. 6 is a diagram showing the internal configuration of a drive circuit along with a plurality of memory cells connected to the drive circuit according to the first embodiment of the present disclosure.

FIG. 7 is a diagram showing one memory cell along with a circuit peripheral to it according to the first embodiment of the present disclosure.

FIG. 8 is a diagram showing some signal waveforms and voltage waveforms in the storage circuit according to the first embodiment of the present disclosure.

FIG. 9 is a diagram showing a state in the pre-charge period in the circuit configuration in FIG. 7 according to the first embodiment of the present disclosure.

FIG. 10 is a diagram showing a state in the read period in the circuit configuration in FIG. 7 according to the first embodiment of the present disclosure.

FIG. 11 is a diagram showing the states of switches during execution of the first program operation in the circuit configuration in FIG. 7 according to the first embodiment of the present disclosure.

FIG. 12 is a diagram showing the states of switches during execution of the second program operation in the circuit configuration in FIG. 7 according to the first embodiment of the present disclosure.

FIG. 13 is a diagram showing a specific example of an adjustment circuit according to the first embodiment of the present disclosure.

FIG. 14A is a diagram showing a relationship of an adjustment transistor with transistors in a memory cell according to the first embodiment of the present disclosure.

FIG. 14B is a diagram showing a relationship of an adjustment transistor with transistors in a memory cell according to the first embodiment of the present disclosure.

FIG. 15 is a diagram showing an example of the behavior of a boost voltage according to the first embodiment of the present disclosure.

FIG. 16 is a diagram showing a configuration example of a memory cell according to a second embodiment of the present disclosure.

### DESCRIPTION OF EMBODIMENTS

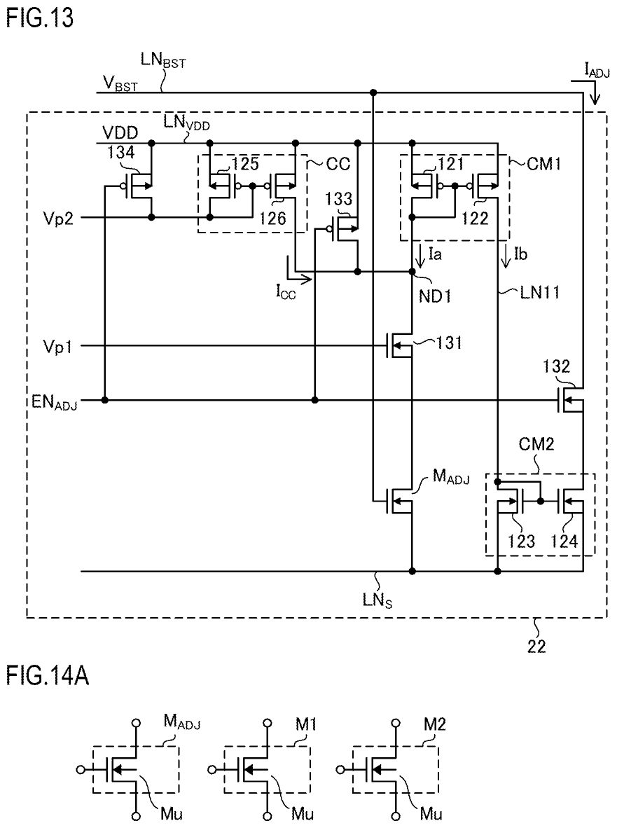

Hereinafter, examples of implementing the present disclosure will be described specifically with reference to the accompanying drawings. Among the diagrams referred to in the course, the same parts are identified by the same reference signs, and in principle no overlapping description of the same parts will be repeated. In the present description, for the sake of simplicity, symbols and reference signs referring to information, signals, physical quantities, elements, parts, and the like are occasionally used with omission or abbreviation of the names of the information, signals, physical quantities, elements, parts, and the like corresponding to those symbols and reference signs. For example, the adjustment transistor described later and identified by the reference sign “M_{ADJ}” (see FIG. 13) is sometimes referred to as the adjustment transistor M_{ADJ} and other times abbreviated to the transistor M_{ADJ}, both referring to the same entity.

First, some of the terms used to describe embodiments of the present disclosure will be defined. “Line” refers to a wiring (conductor) across which an electrical signal is transmitted or to which one is applied. “Ground” refers to a reference conductor at a reference potential of 0 V (zero volts), or to a potential of 0 V itself. A reference conductor is formed of an electrically conductive material such as metal. A potential of 0 V is occasionally referred to as a ground potential. In embodiments of the present disclosure, any voltage mentioned with no particular reference mentioned is a potential relative to the ground. “Level” denotes the level of a potential, and for any signal or voltage of interest, “high level” has a higher potential than “low level”. For any signal or voltage of interest, its being at high level means its level being equal to high level, and its being at low level means its level being equal to low level. A level of a signal is occasionally referred to as a signal level, and a level of a voltage is occasionally referred to as a voltage level.

For any signal of interest, when the signal of interest is at high level, the inversion signal of that signal of interest is at low level; when the signal of interest is at low level, the inversion signal of that signal of interest is at high level. For any signal or voltage of interest, a transition from low level to high level is termed an up edge (or rising edge), and a transition from high level to low level is termed a down edge (or falling edge).

For any transistor configured as an FET (field-effect transistor), which can be a MOSFET, “on state” refers to a state where the drain-source channel of the transistor is conducting, and “off state” refers to a state where the drain-source channel of the transistor is not conducting (cut off). Similar definitions apply for any transistor that is not classified as an FET. Unless otherwise stated, any MOSFET can be understood to be an enhancement MOSFET. “MOSFET” is an abbreviation of “metal-oxide-semiconductor field-effect transistor”.

The electrical characteristics of a MOSFET include the gate threshold voltage. For any transistor that is an N-channel enhancement MOSFET, when the gate potential of the transistor is higher than the source potential of the transistor and the magnitude of the gate-source voltage (the gate potential relative to the source potential) of the transistor is equal to or higher than the gate threshold voltage of the transistor, the transistor is in the on state; otherwise, the transistor is in the off state.

Any switch can be configured with one or more FETs (field-effect transistors). When a given switch is in the on state, the switch conducts across its terminals; when a given switch is in the off state, the switch does not conduct across its terminals. For any transistor or switch, its being in the on or off state is occasionally expressed simply as its being on or off respectively. For any signal that takes as its signal level high level or low level, the period in which the signal is at high level is referred to as the high-level period and the period in which the signal is at low level is referred to as the low-level period. The same applies to any voltage that takes as its voltage level high level or low level.

### First Embodiment

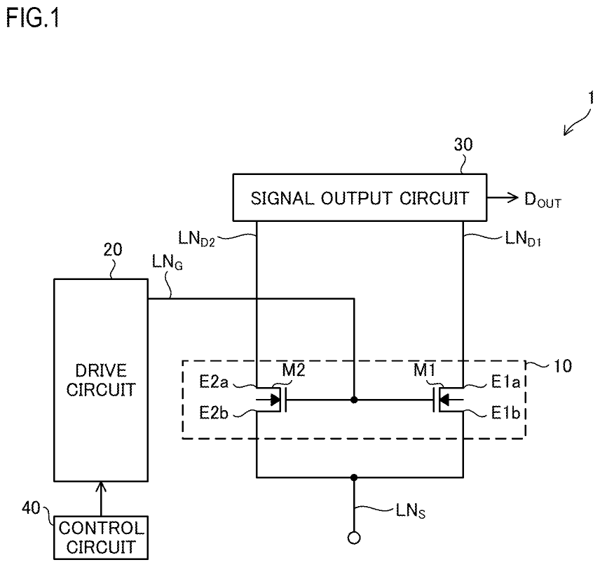

A first embodiment of the present disclosure will be described. FIG. 1 is a configuration diagram of a principal part of a storage circuit 1 according to a first embodiment. The storage circuit 1 is a non-volatile memory that stores data corresponding to a predetermined number of bits, and includes a memory cell 10, a drive circuit 20, a signal output circuit 30, and a control circuit 40. FIG. 1 focuses on one memory cell 10 included in the storage circuit 1. One memory cell 10 can store data corresponding to one bit on a non-volatile basis. While the storage circuit 1 may include a plurality of memory cells 10, here attention is paid to only one memory cell 10. The storage circuit 1 may be a non-volatile memory that includes only one memory cell 10 as a memory cell (that is, the predetermined number of bits mentioned above may be one bit). The storage circuit 1 may be configured as a semiconductor integrated circuit. The control circuit 40 controls the operation of the drive circuit 20. The control circuit 40 may also control the operation of the signal output circuit 30.

The memory cell 10 includes memory elements M1 and M2, and stores either data of “0” or data of “1”. The memory elements M1 and M2 are each a transistor. Accordingly, the memory elements M1 and M2 will be referred to also as transistors M1 and M2 (a first and a second transistor). The transistors M1 and M2 are each configured as an N-channel MOSFET.

The transistor M1 has a gate, an electrode E1a, and an electrode E1b. In the transistor M1, of the electrodes E1a and E1b, the one at the high potential side functions as the drain and the one at the low potential side functions as the source. In the transistor M1, while in principle the electrode E1b functions as the source, the electrode E1b can function as the drain during execution of a program operation, which will be described later. The transistor M2 has a gate, an electrode E2a, and an electrode E2b. In the transistor M2, of the electrodes E2a and E2b, the one at the high potential side functions as the drain and the one at the low potential side functions as the source. In the transistor M2, while in principle the electrode E2b functions as the source, the electrode E2b can function as the drain during execution of a program operation, which will be described later.

The transistors M1 and M2 have their gates connected together to a gate line LN_{G}.

The gates of the transistors M1 and M2 are connected via the gate line LN_{G} to the drive circuit 20. The electrode E1b of the transistor M1 and the electrode E2b of the transistor M2 are connected together to a line LN_{S}. The electrodes E1b and E2b basically function as sources, and accordingly the line LN_{S} will hereinafter be referred to also as the source line LN_{S}. The electrode E1a of the transistor M1 is connected to the line LN_{D1}, and is connected via the line LN_{D1} to the signal output circuit 30. The electrode E2a of the transistor M2 is connected to the line LN_{D2}, and is connected via the line LN_{D2} to the signal output circuit 30. The electrode E1a and E2a basically function as drains, and accordingly the lines LN_{D1} and LN_{D2} will hereinafter be referred to also as the drain lines LN_{D1} and LN_{D2}.

In the storage circuit 1 are performed, under the control of the control circuit 40, a read operation for reading the data stored in the memory cell 10 and a program operation (write operation) for writing data (value) to the memory cell 10 or for rewriting the data (value) stored in the memory cell 10. In this embodiment, the expressions “before execution of the program operation” and “before the program operation” are synonymous, and the expressions “after execution of the program operation” and “after the program operation” are synonymous (the same applies to the description of another embodiment presented later).

In the storage circuit 1, when the read operation is performed, a pre-charge period precedes its execution, and in a read period subsequent to the pre-charge period, the read operation is performed. In the read operation, based on the magnitude relationship between the drain currents in the transistors M1 and M2 in the read period, the data stored in the memory cell 10 is read out.

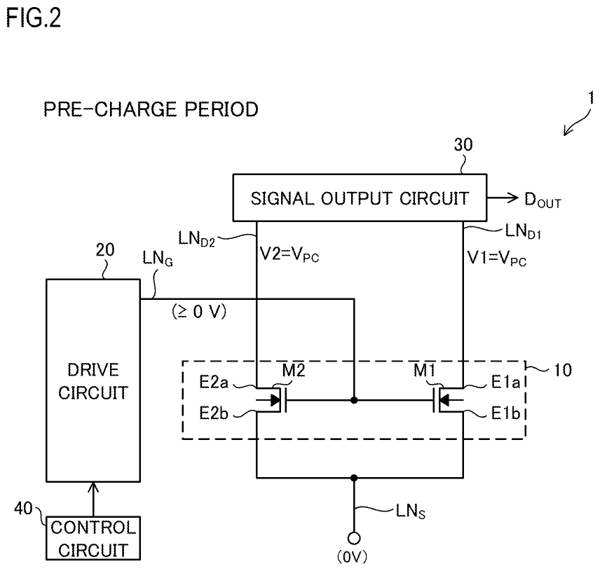

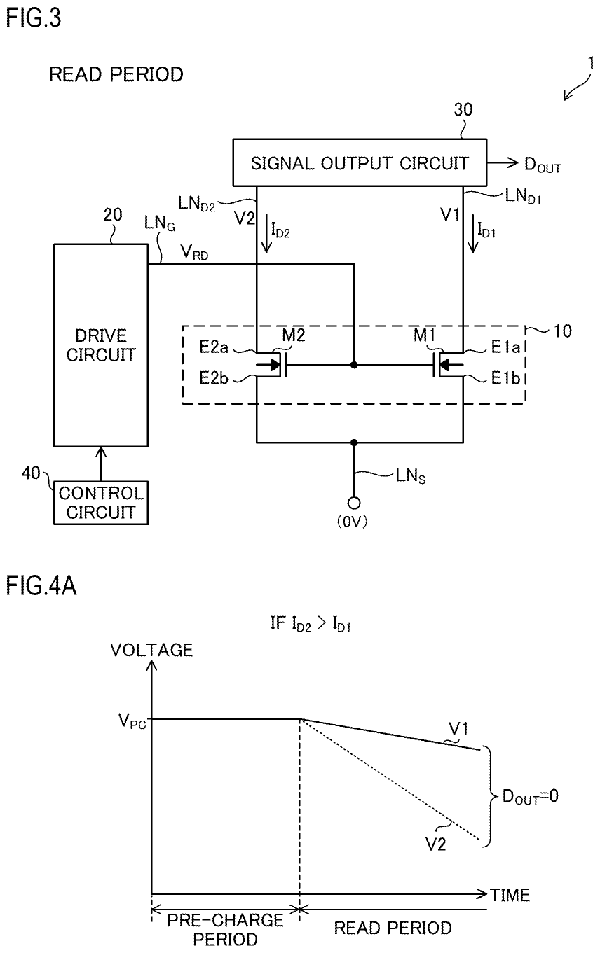

FIGS. 2 and 3 show the states of voltages or currents in the pre-charge and read periods. The control and application of relevant voltages in the pre-charge and read periods are performed under the control of the control circuit 40. In the pre-charge and read periods, the voltage on the source line LN_{S} is set to 0 V, with the electrodes E1a and E2a functioning as the drains and the electrodes E1b and E2b functioning as the sources. The voltage on the drain line LN_{D1} will be referred to as the voltage V1, and the voltage on the drain line LN_{D2} will be referred to as the voltage V2. In the pre-charge period, the drive circuit 20 sets the gate voltages of the transistors M1 and M2 to 0 V, and the drain lines LN_{D1} and LN_{D2} are each supplied with a positive electric charge so that a common pre-charge voltage V_{PC} is set with respect to the voltages V1 and V2 on the drain lines LN_{D1} and LN_{D2}. The pre-charge voltage V_{PC} has a predetermined positive direct-current voltage value (e.g., 1 V). The positive electric charge mentioned above can be supplied from the signal output circuit 30 or from an unillustrated circuit. In the pre-charge period, the gates of the transistors M1 and M2 may each be fed with a positive voltage. In any case, in the pre-charge period, the voltages V1 and V2 are kept at the pre-charge voltage V_{PC}.

After the pre-charge period, the gates of the transistors M1 and M2 are each fed with a positive read voltage V_{RD}, and this starts the read period. The read voltage V_{RD} can be a constant direct-current voltage, or can be a voltage that varies slightly with the passage of time in the read period. The read voltage V_{RD} is higher than at least one of the gate threshold voltages of the transistors M1 and M2. The drain currents in the transistors M1 and M2 in the read period will be identified by the symbols “I_{D1}” and “I_{D2}” respectively. Note that, in the read period, the input impedances of the signal output circuit 30 as seen from the drain lines LN_{D1} and LN_{D2} respectively are set to be sufficiently high. As a result, in the read period, only the passage of a drain current I_{D1} causes the voltage V1 on the drain line LN_{D1} to fall, and only the passage of a drain current I_{D2} causes the voltage V2 on the drain line LN_{D2} to fall.

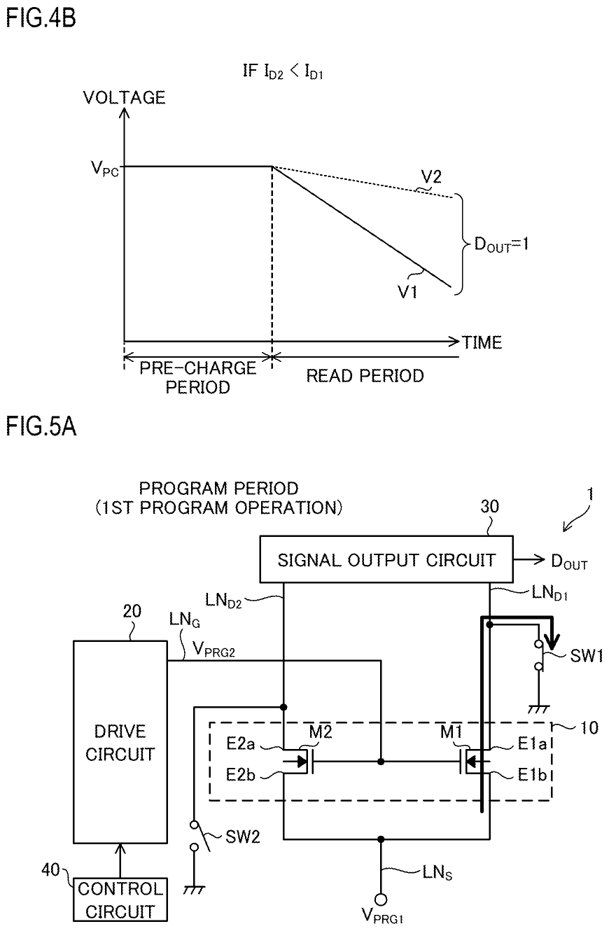

FIG. 4A schematically shows the behavior of the voltages V1 and V2 in the pre-charge and read periods as observed when I_{D2}>I_{D1} in the read period. FIG. 4B schematically shows the behavior of the voltages V1 and V2 in the pre-charge and read periods as observed when I_{D2}<I_{D1} in the read period. In the read operation, based on the magnitude relationship of the drain currents in the transistors M1 and M2, the signal output circuit 30 outputs a signal D_{OUT} corresponding to the value of the data stored in the memory cell 10.

In the read operation (in other words, in the read period), a state where the drain current I_{D2} is higher than the drain current I_{D1} corresponds to a state where a first value is stored in the memory cell 10. Accordingly, if in the read operation the drain current I_{D2} is higher than the drain current I_{D1}, the signal output circuit 30 outputs a signal D_{OUT} associated with the first value (in other words, a signal D_{OUT} representing the first value). In the read operation (in other words, in the read period), a state where the drain current I_{D1} is higher than the drain current I_{D2} corresponds to a state where a second value is stored in the memory cell 10. Accordingly, if in the read operation the drain current I_{D1} is higher than the drain current I_{D2}, the signal output circuit 30 outputs a signal D_{OUT} associated with the second value (in other words, a signal D_{OUT} representing the second value). It is here assumed that the first value is “0” and that the second value is “1”.

In the storage circuit 1 according to the first embodiment, the transistors M1 and M2 have the same structure. Accordingly, in the storage circuit 1 in its initial state, the magnitude relationship between the drain currents I_{D1} and I_{D2} is indefinite, and thus the value stored in the memory cell 10 also is indefinite. The initial state of the storage circuit 1 corresponds to a state where the program operation, described later, has not ever been performed.

With respect to a transistor, “structure” is a concept that covers size. Accordingly, with respect to a plurality of transistors, their having the same structure means that they have the same size as well. When a given plurality of transistors have the same structure, unless part or all of them have been subjected to hot carrier injection through the program operation, those transistors have the same electrical characteristics (including gate threshold voltage). Note however that, with respect to any plurality of transistors, their having the same structure or electrical characteristics simply means that they do so in design and allows for errors in practice (that is, “the same” should be understood to conceptually allow for errors).

In the storage circuit 1, as the program operation, either a first program operation or a second program operation is alternatively performed.

In the first program operation, hot carriers are injected into, out of the transistors M1 and M2, only the transistor M1, with the result that the gate threshold voltage of the transistor M1 is increased. The first program operation is executed such that after its execution the gate threshold voltage of the transistor M1 is sufficiently higher than the gate threshold voltage of the transistor M2. The gate threshold voltage of the transistor M1 after execution of the first program operation may be higher than the read voltage V_{RD}. Accordingly, in the read operation executed after the first program operation, as the result of the increase in the gate threshold voltage of the transistor M1 during the first program operation, I_{D2}>I_{D1} as shown in FIG. 4A, and consequently a signal D_{OUT} representing the first value (0) is output. That is, the data (value) of “0” stored in the memory cell 10 is read out.

In the second program operation, hot carriers are injected into, out of the transistors M1 and M2, only the transistor M2, with the result that the gate threshold voltage of the transistor M2 is increased. The second program operation is executed such that after its execution the gate threshold voltage of the transistor M2 is sufficiently higher than the gate threshold voltage of the transistor M1. The gate threshold voltage of the transistor M2 after execution of the second program operation may be higher than the read voltage V_{RD}. Accordingly, in the read operation executed after the second program operation, as the result of the increase in the gate threshold voltage of the transistor M2 during the second program operation, I_{D2}<I_{D1} as shown in FIG. 4B, and consequently a signal D_{OUT} representing the second value (1) is output. That is, the data (value) of “1” stored in the memory cell 10 is read out.

In the following description, it is assumed that a low-level signal D_{OUT} represents the first value (0) and that a high-level signal D_{OUT} represents the second value (1). Then, for example by identifying whichever of the voltages V1 and V2 becomes equal to or lower than a predetermined voltage first after the start of the read period, the signal output circuit 30 can determine the level of the signal D_{OUT}. If the identified voltage is the voltage V2, it indicates that I_{D2}>I_{D1}, and thus a low-level signal D_{OUT} (a signal D_{OUT} representing the value “0”) is output. If the identified voltage is the voltage V1, it indicates that I_{D2}<I_{D1}, and thus a high-level signal D_{OUT} (a signal D_{OUT} representing the value “1”) is output. Instead, for example, a time point at the lapse of a predetermined time from the start of the read period can be taken as a read time point, and the magnitude relationship between the voltages V1 and V2 at the read time point may be sensed to find out the magnitude relationship between the drain currents I_{D1} and I_{D2}.

A description of the program operation continues. A period in which the program operation is performed will be referred to as the program period. The control and application of relevant voltages in the program period are performed under the control of the control circuit 40.

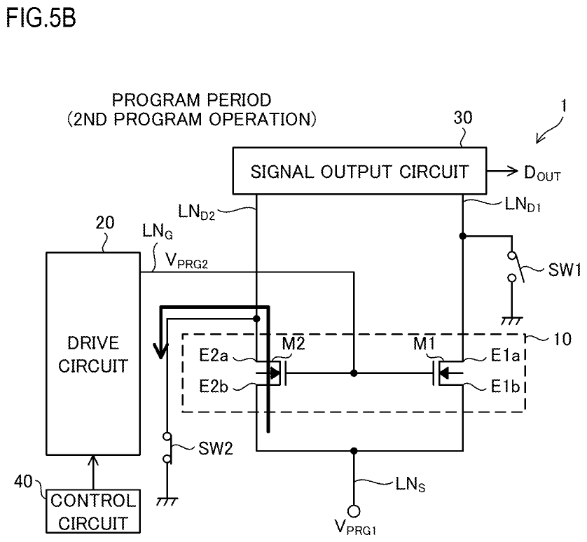

FIG. 5A shows the state of the storage circuit 1 in the program period in which the first program operation is performed. In the first program operation, the storage circuit 1 injects hot carriers into, out of the transistors M1 and M2, only the transistor M1, and thereby changes the electrical characteristics of the transistor M1. The change increases (raises) the gate threshold voltage of the transistor M1. FIG. 5B shows the state of the storage circuit 1 in the program period in which the second program operation is performed. In the second program operation, the storage circuit 1 injects hot carriers into, out of the transistors M1 and M2, only the transistor M2, and thereby changes the electrical characteristics of the transistor M2. The change increases (raises) the gate threshold voltage of the transistor M2.

In the first and second program operations (hence in the program period), a positive voltage V_{PRG1} is applied to the line LN_{S} and, by the drive circuit 20, a positive voltage V_{PRG2} is applied to each of the gates of the transistors M1 and M2. The voltage V_{PRG2} may have the same voltage value as the read voltage V_{RD}, or may be higher than the read voltage V_{RD}. The voltages V_{PRG1} and V_{PRG2} may or may not be equal. The voltages V_{PRG1} and V_{PRG2} may be of any magnitudes so long as they can raise the gate threshold voltage of the transistor M1 as desired in the first program operation and the gate threshold voltage of the transistor M2 as desired in the second program operation.

The storage circuit 1 includes switches SW1 and SW2, though omitted from illustration in FIG. 1 etc. The switch SW1 is inserted between the electrode E1a of the transistor M1 and the ground, and the switch SW2 is inserted between the electrode E2a of the transistor M2 and the ground. The control circuit 40 turns on and off the switches SW1 and SW2 individually. The switches SW1 and SW2 are both in principle off. Only in the program period of the first program operation is the switch SW1 on, and only in the program period of the second program operation is the switch SW2 on. In the program period of the first program operation, the switch SW2 is off, and in the program period of the second program operation, the switch SW1 is off.

Accordingly, in the first program operation (in the program period of the first program operation), in the transistor M1, the electrode E1b functions as the drain and the electrode E1a as the source, so that a current passes from the line LN_{S} via the electrodes E1b and E1a and the switch SW1 to the ground. While this current is passing, hot carriers are injected into the transistor M1 and the characteristics of the transistor M1 change such that its gate threshold voltage increases. The program period is maintained for a length of time required for a sufficient increase in the gate threshold voltage of the transistor M1, and then the first program operation ends. So that this effect can be achieved by the first program operation, the voltages V_{PRG1} and V_{PRG2} can be given sufficiently high voltage values. Incidentally, in the program period of the first program operation, the line LN_{D2} is in a high-impedance state. It can be understood that, in the program period of the first program operation, the voltage V_{PRG2} is applied to the line LN_{D2}. In any case, in the program period of the first program operation, no current passes between the electrodes E2a and E2b.

Likewise, in the second program operation (in the program period of the second program operation), in the transistor M2, the electrode E2b functions as the drain and the electrode E2a as the source, so that a current passes from the line LN_{S} via the electrodes E2b and E2a and the switch SW2 to the ground. While this current is passing, hot carriers are injected into the transistor M2 and the characteristics of the transistor M2 change such that its gate threshold voltage increases. The program period is maintained for a length of time required for a sufficient increase in the gate threshold voltage of the transistor M2, and then the second program operation ends. So that this effect can be achieved by the second program operation, the voltages V_{PRG1} and V_{PRG2} can be given sufficiently high voltage values. Incidentally, in the program period of the second program operation, the line LN_{D1} is in a high-impedance state. It can be understood that, in the program period of the second program operation, the voltage V_{PRG2} is applied to the line LN_{D1}. In any case, in the program period of the second program operation, no current passes between the electrodes E1a and E1b.

The first and second program operations can be achieved in any other manner than described above. For example, in the program period of the first program operation, with the gates of the transistors M1 and M2 each fed with the voltage V_{PRG2}, out of the lines LN_{D1} and LN_{D2}, only the line LN_{D1} is fed with the voltage V_{PRG1} and the line LN_{S} is fed with the ground potential. This too achieves the first program operation. Meanwhile, the switch SW1 is kept off, and the line LN_{D2} is fed with the ground potential or is kept in a high-impedance state. This too permits hot carriers to be injected, out of the transistors M1 and M2, only the transistor M1. Likewise, for example, in the program period of the second program operation, with the gates of the transistors M1 and M2 each fed with the voltage V_{PRG2}, out of the lines LN_{D1} and LN_{D2}, only the line LN_{D2} is fed with the voltage V_{PRG1} and the line LN_{S} is fed with the ground potential. This too achieves the second program operation. Meanwhile, the switch SW2 is kept off, and the line LN_{D1} is fed with the ground potential or is kept in a high-impedance state. This too permits hot carriers to be injected, out of the transistors M1 and M2, only the transistor M2.

Since the gate threshold voltage of the memory elements (M1, M2) in a non-volatile memory is comparatively high, in a case where a comparatively low supply voltage is used, it is expedient to use a charge pump to generate the read voltage V_{RD}. In that case, from the perspectives of circuit size reduction and the like, the charge pump is built with a simple configuration without use of a diode or a large output capacitor. This inconveniently makes it difficult to feed an accurate read voltage V_{RD} to the gates of the memory elements (M1, M2).

Moreover, the relationship of the gate-source voltage with the drain current in the memory elements (M1, M2) varies greatly with element-to-element variation and temperature variation. Thus, even if the read voltage V_{RD} is constant, the drain current in the memory elements (M1, M2) in the read operation varies in different ways. The drain current in the memory elements (M1, M2) in the read operation varies even more if the read voltage V_{RD} varies.

On the other hand, an excessively high drain current in the memory elements (M1, M2) in the read operation leads to increased power consumption. From the perspective of power saving, it is preferable to reduce the drain current in the read operation. Too low a drain current in them, however, makes it difficult to read the stored data in the memory cell 10 in a limited time. It is therefore preferable, in the read operation, to pass through the transistor M1 or M2 a drain current of an adequate magnitude that does not depend on element-to-element variation or temperature variation (i.e., to limit the range of variation of the magnitude of the drain current). Meeting this requirement helps achieve power saving. Moreover, if the drain current in the transistor M1 or M2 in the read operation varies greatly, a circuit peripheral to it (e.g., a circuit as the source of the current and a switch on the path of the current) need to be configured with consideration given to the maximum value of the drain current as designed, and this increases the size of the peripheral circuit. Here, limiting the range of variation of the magnitude of the drain current permits size reduction in the peripheral circuit. Furthermore, if the drain current in the transistor M1 or M2 in the read operation varies greatly, this adversely affects the characteristics of the non-volatile memory. Here, limiting the range of variation of the magnitude of the drain current (ideally making it constant) is expected to improve the characteristics of the non-volatile memory.

Out of the considerations above, circuit configurations will be presented below that optimize the drain current in the memory elements (M1, M2) in the read operation.

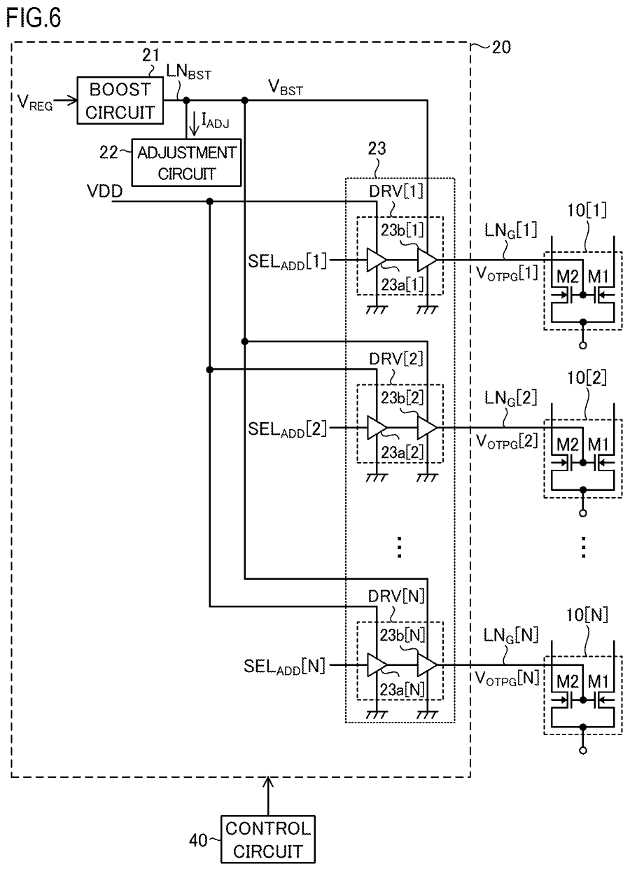

FIG. 6 shows the internal configuration of the drive circuit 20 along with a plurality of memory cells connected to the drive circuit 20. While FIG. 1 focuses on one memory cell 10 provided in the storage circuit 1, the storage circuit 1 may be a non-volatile memory that can store data corresponding to a plurality of bits as mentioned earlier. In the following description, it is assumed that the storage circuit 1 has a first to an nth address defined in it and includes memory cells 10 one for each address. Here, N is any integer of two or more, though a modification such that N=1 is possible (in that case, the total number of address is one).

The memory cell 10 assigned to the ith address will be referred to specifically as the memory cell 10[i] (where i is an integer). While the storage circuit 1 may include a plurality of memory cells for each address so that it can store data corresponding to a plurality of bits at each address, FIG. 6 only shows memory cells 10[i] each corresponding to one bit per address. The memory cells 10[1] to 10[N] all have the same configuration.

The gate line LN_{G} corresponding to the memory cell 10 with the ith address (i.e., the memory cell 10[i]) will be identified specifically by the symbol “LN_{G}[i]”. The gate line LN_{G}[i] is connected to each of the gates of the transistors M1 and M2 within the memory cell 10[i]. The Drive Circuit 20 Feeds the Gate Lines LN_{G}[i] to LN_{G}[N] with Gate voltages V_{OTPG}[i] to V_{OTPG}[N] respectively, and thereby feeds gate voltages to the transistors M1 and M2 at the corresponding addresses. The gate voltage V_{OTPG}[i] is a voltage applied to the gate line LN_{G}[i], and is fed to each of the gates of the transistors M1 and M2 within the memory cell 10[i].

The drive circuit 20 includes a boost circuit 21, an adjustment circuit 22, and a gate voltage feed circuit 23.

The boost circuit 21 boosts a predetermined reference voltage V_{REG} generated within the drive circuit 20, and thereby generates a boost voltage V_{BST} resulting from boosting the reference voltage V_{REG}. The boost voltage V_{BST} appears on a boost line LN_{BST}. The reference voltage V_{REG} has a predetermined positive direct-current voltage value (e.g., 1.6 V). The boost circuit 21, of which a specific example will be described later, can be a charge pump circuit configured with one or more capacitors and one or more switches. In that case, the boost voltage V_{BST} varies in a manner coordinated with the operation of the charge pump circuit, and at least in the process of that variation the maximum voltage of the boost voltage V_{BST} is higher than the reference voltage V_{REG}. A supply voltage VDD corresponds to the supply voltage for the storage circuit 1, and has a predetermined positive direct-current voltage value.

The adjustment circuit 22 is connected to the boost line LN_{BST}, and adjusts the boost voltage V_{BST} by drawing from the boost line LN_{BST} an adjustment current I_{ADJ} commensurate with the boost voltage V_{BST}. The adjustment circuit 22, of which a specific example will be described later, adjusts the boost voltage V_{BST} such that it has a voltage level adequate for the read operation.

The gate voltage feed circuit 23 feeds gate voltages to the transistors in the memory cells 10[1] to 10[N] respectively. The gate voltage feed circuit 23 includes gate drivers provided one for each address. The gate driver corresponding to the ith address will be identified by the symbol “DRV [i]”. Then the gate voltage feed circuit 23 is composed of gate drivers DRV[1] to DRV[N]. Each gate driver includes a first and a second buffer. The first and second buffers provided in the gate driver DRV[i] will be identified by the symbols “23a[i]” and “23b[i]” respectively. The control circuit 40 (see FIG. 1) feeds the gate drivers DRV[1] to DRV[N] with address selection signals SEL_{ADD}[1] to SEL_{ADD}[N] respectively. Each address selection signal is a digital signal that takes as its signal level high or low level. Each address selection signal has, when at high level, substantially the potential of the supply voltage VDD and, when at low level, substantially the ground potential.

The gate drivers DRV[1] to DRV[N] all have the same configuration, so a description will be given below of the configuration and operation of one of them, specifically the gate driver DRV[i] (hence the configuration and operation of the buffers 23a[i] and 23b[i]).

The buffer 23a[i] has an input terminal and an output terminal. The input terminal of the buffer 23a[i] is fed with the address selection signal SEL_{ADD}[i]. When the address selection signal SEL_{ADD}[i] is at high or low level, the buffer 23a[i] outputs from its output terminal a high- or low-level signal respectively. The buffer 23a[i] is a buffer that uses the supply voltage VDD as the high potential-side supply voltage and the ground voltage as the low potential-side supply voltage. Accordingly, the output signal of the buffer 23a[i] has, when at high level, substantially the potential of the supply voltage VDD and, when at low level, substantially the ground potential.

The buffer 23b[i] has an input terminal and an output terminal. The output terminal of the buffer 23a[i] is connected to the input terminal of the buffer 23b[i]. When the output signal of the buffer 23a[i] is at high or low level, the buffer 23b[i] outputs from its output terminal a high- or low-level signal respectively. The buffer 23b[i] is a buffer that uses the boost voltage V_{BST} as the high potential-side supply voltage and the ground voltage as the low potential-side supply voltage. Accordingly, the output signal of the buffer 23b[i] has, when at high level, substantially the potential of the boost voltage V_{BST} and, when at low level, substantially the ground potential. The output signal of the buffer 23b[i] is fed as the gate voltage V_{OTPG}[i] to the gate line LN_{G}[i].

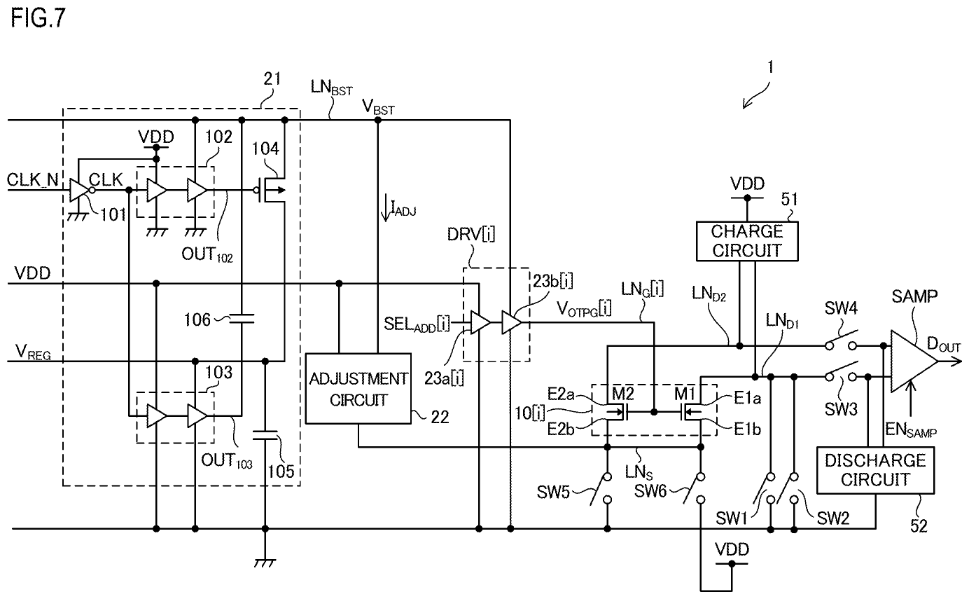

FIG. 7 shows a configuration example of any one memory cell 10[i] among the memory cells 10[1] to 10[N] and a circuit peripheral to it. FIG. 7 also shows a circuit example of the boost circuit 21.

The boost circuit 21 shown in FIG. 7 will be described. The boost circuit 21 in FIG. 7 is configured as a charge pump circuit that includes an inverter 101, level shifters 102 and 103, a transistor 104, and capacitors 105 and 106. The transistor 104 is a P-channel MOSFET, and functions as a switch in the charge pump circuit.

The inverter 101 receives a clock signal CLK_N and outputs a clock signal CLK that is the inversion signal of the clock signal CLK_N. Accordingly, when the clock signal CLK_N is at high or low level, the clock signal CLK is at low or high level respectively. The inverter 101 operates from the supply voltage VDD, and the clock signals CLK_N and CLK each have, when at high level, substantially the potential of the supply voltage VDD and, when at low level, the ground potential. The clock signal CLK_N is output from a clock feed circuit (not illustrated) provided inside or outside the storage circuit 1.

The level shifter 102, using the supply voltage VDD and the boost voltage V_{BST}, shifts the high level-side potential of the clock signal CLK output from the inverter 101 to the potential of the boost voltage V_{BST}. The output signal OUT₁₀₂ of the level shifter 102 resulting from the shifting is fed to the gate of the transistor 104. When the clock signal CLK is at high or low level, the output signal OUT₁₀₂ of the level shifter 102 too is at high or low level respectively. Note however that the high level of the output signal OUT₁₀₂ is substantially the potential of the boost voltage V_{BST}. The low level of the output signal OUT₁₀₂ is substantially the ground potential. The level shifter 102 can be configured with a series circuit of a first buffer that uses the supply voltage VDD as the high potential-side supply voltage and the ground voltage as the low potential-side supply voltage and a second buffer that uses the boost voltage V_{BST} as the high potential-side supply voltage and the ground voltage as the low potential-side supply voltage.

The level shifter 103, using the supply voltage VDD and the reference voltage V_{REG}, shifts the high level-side potential of the clock signal CLK output from the inverter 101 to the potential of the reference voltage V_{REG}. The output signal OUT₁₀₃ of the level shifter 103 resulting from the shifting is fed to one terminal of the capacitor 106. The other terminal of the capacitor 106 is connected to the boost line LN_{BST}. When the clock signal CLK is at high or low level, the output signal OUT₁₀₃ of the level shifter 103 too is at high or low level respectively. Note however that the high level of the output signal OUT₁₀₃ is substantially the potential of the reference voltage V_{REG}. The low level of the output signal OUT₁₀₃ is substantially the ground potential. The level shifter 103 can be configured with a series circuit of a third buffer that uses the supply voltage VDD as the high potential-side supply voltage and the ground voltage as the low potential-side supply voltage and a fourth buffer that uses the reference voltage V_{REG} as the high potential-side supply voltage and the ground voltage as the low potential-side supply voltage.

In the boost circuit 21, the inverter 101 may be omitted, in which case the clock signal CLK can be fed directly to the level shifters 102 and 103.

The source of the transistor 104 is connected to the boost line LN_{BST}. The drain of the transistor 104 and one terminal of the capacitor 105 are together connected to a line to which the reference voltage V_{REG} is applied. The other terminal of the capacitor 105 is connected to the ground.

As a circuit peripheral to the memory cell 10[i], the storage circuit 1 includes switches SW1 to SW6, a charge circuit 51, and a discharge circuit 52. A sense amplifier SAMP is a component of the signal output circuit 30, and corresponds to the signal output circuit 30 for the memory cell 10[i]. In the read operation with respect to the memory cell 10[i], the sense amplifier SAMP outputs a signal D_{OUT} representing the stored data in the memory cell 10[i]. The switches SW1 to SW6 are turned on and off individually by the control circuit 40. FIG. 7 shows a state where the switches SW1 to SW6 are all off.

While the switches SW1 to SW6, the charge circuit 51, and the discharge circuit 52 may be shared among the memory cells 10[1] to 10[N], FIG. 7 only shows the relationship among one memory cell 10[i], the switches SW1 to SW6, the charge circuit 51, and the discharge circuit 52. A modification is possible where a set of the switches SW1 to SW6, the charge circuit 51, and the discharge circuit 52 is provided for each of the memory cells 10[1] to 10[N].

In the memory cell 10[i], the electrode E1b of the transistor M1 and the electrode E2b of the transistor M2 are connected together to the source line LN_{S}, and this source line LN_{S} is connected to one terminal of the switch SW5 and to one terminal of the switch SW6. The other terminal of the switch SW5 is connected to the ground, and the other terminal of the switch SW6 is connected to a line to which the supply voltage VDD is applied.

In the memory cell 10[i], the electrode E1a of the transistor M1 is connected to the drain line LN_{D1}, and this drain line LN_{D1} is connected to one terminal of the switch SW3, with the other terminal of the switch SW3 connected to the first input terminal of the sense amplifier SAMP. Between the connection node of the drain line LN_{D1} with one terminal of the switch SW3 and the ground, the switch SW1 is inserted in series.

In the memory cell 10[i], the electrode E2a of the transistor M2 is connected to the drain line LN_{D2}, and this drain line LN_{D2} is connected to one terminal of the switch SW4, with the other terminal of the switch SW4 connected to the second input terminal of the sense amplifier SAMP. Between the connection node of the drain line LN_{D2} with one terminal of the switch SW4 and the ground, the switch SW2 is inserted in series.

In the memory cell 10[i], the gates of the transistors M1 and M2 are connected together to the gate line LN_{G}[i], and are fed with the gate voltage V_{OTPG}[i] from the gate driver DRV[i].

The charge circuit 51 is connected via two mutually different lines to the drain lines LN_{D1} and LN_{D2} respectively. The discharge circuit 52 is connected via other two mutually different lines to the first and second input terminals, respectively, of the sense amplifier SAMP. Under the control of the control circuit 40, the charge circuit 51 can whenever necessary feed a charge (positive charge) based on the supply voltage VDD to the drain lines LN_{D1} and LN_{D2}. Under the control of the control circuit 40, the discharge circuit 52 can whenever necessary draw a charge (positive charge) from the drain lines LN_{D1} and LN_{D2} (assuming that the switches SW3 and SW4 are on).

The sense amplifier SAMP is fed with an enable signal EN_{SAMP}. When the enable signal EN_{SAMP} is at low level, the sense amplifier SAMP is in a reset state and does not output any significant signal. When the enable signal EN_{SAMP} is at high level, the sense amplifier SAMP is out of the reset state and can output the signal D_{OUT} representing the stored data in the memory cell 10[i].

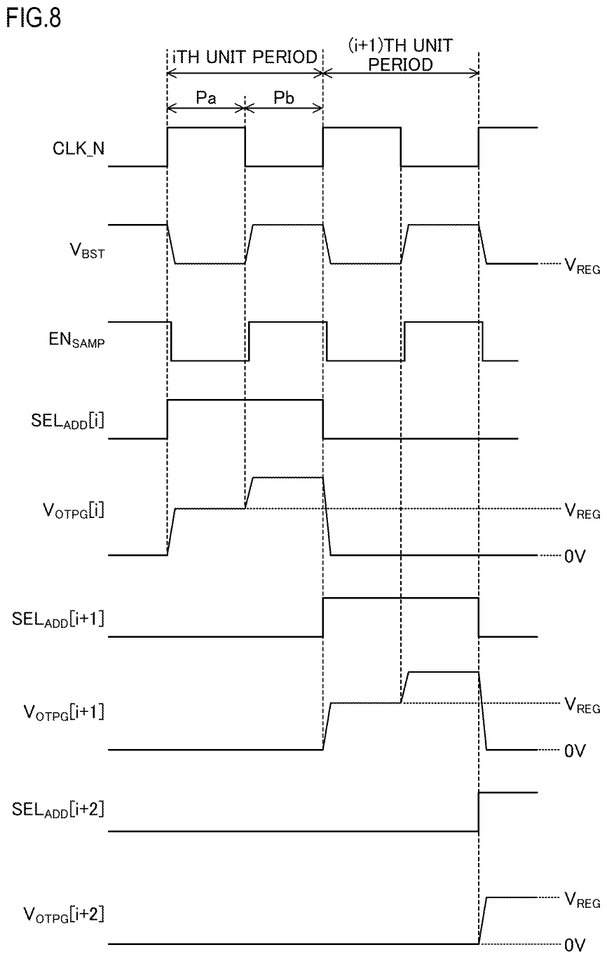

FIG. 8 shows the waveforms of the clock signal CLK_N, the boost voltage V_{BST} and the enable voltage EN_{SAMP} along with the waveforms of address selection signals and gate signals corresponding to three addresses. Shown in FIG. 8 as the waveforms of address selection signals and gate signals corresponding to three addresses are those of an address selection signal SEL_{ADD}[i] and a gate voltage V_{OTPG}[i] corresponding to the ith address, an address selection signal SEL_{ADD}[i+1] and a gate voltage V_{OTPG}[i+1] corresponding to the (i+1)th address, and an address selection signal SEL_{ADD}[i+2] and a gate voltage V_{OTPG}[i+2] corresponding to the (i+2)th address (in FIG. 8, i is assumed to be a natural number of (N−2) or less).

Based on the clock signal CLK_N (or a clock signal corresponding to the inversion signal of the clock signal CLK_N), the control circuit 40 turns to high level the address selection signals SEL_{ADD}[1] to SEL_{ADD}[N] sequentially, one by one, every period of the clock signal CLK_N. More specifically, this proceeds, if a period of the length equal to one period of the clock signal CLK_N is taken as a unit period, as follows. In the first unit period, of the selection signals SEL_{ADD}[1] to SEL_{ADD}[N], only the SEL_{ADD}[1] is turned to high level while all the other address selection signals are kept at low level. In the second unit period, of the selection signals SEL_{ADD}[1] to SEL_{ADD}[N], only the SEL_{ADD}[2] is turned to high level while all the other address selection signals are kept at low level. In the third unit period, similar control takes place. That is, in the ith unit period, of the selection signals SEL_{ADD}[1] to SEL_{ADD}[N], only the SEL_{ADD}[i] is turned to high level while all the other address selection signals are kept at low level. It is here assumed that each unit period starts at an up edge in the clock signal CLK_N (at the time point of its shift from low level to high level).

In the high-level period of the clock signal CLK_N, a low-level output signal OUT₁₀₂ (a signal with the ground potential) is fed from the level shifter 102 to the gate of the transistor 104, and thus the transistor 104 turns on. As a result, in the high-level period of the clock signal CLK_N, the boost voltage V_{BST} is equal to the reference voltage V_{REG}, and in this state an output signal OUT₁₀₃ with the ground potential is fed from the level shifter 103 to one terminal (low-potential terminal) of the capacitor 106; thus the capacitor 106 is charged by the boost voltage V_{BST}.

When the clock signal CLK_N turns from high level to low level, a high-level output signal OUT₁₀₂ (a signal with the potential of the boost voltage V_{BST}) is fed from the level shifter 102 to the gate of the transistor 104, and thus the transistor 104 turns off. Moreover, at this time, the output signal OUT₁₀₃ of the level shifter 103 turns from low level to high level, and thus via the capacitor 106 the boost voltage V_{BST} rises. If no circuit is provided that draws a current from the boost line LN_{BST} in the low-level period of the clock signal CLK_N, the boost voltage V_{BST} will, ideally, rise up to twice the reference voltage V_{REG}. Since unit periods recur, as they do the boost voltage V_{BST} varies between the reference voltage V_{REG} and a voltage higher than the reference voltage V_{REG}.

The enable signal EN_{SAMP} is at high level when the boost voltage V_{BST} is equal to or higher than a predetermined judgement voltage, and is at low level when the boost voltage V_{BST} is lower than the judgement voltage. The judgement voltage is set at a voltage higher than the reference voltage V_{REG} but lower than twice the reference voltage V_{REG}. The storage circuit 1 is provided with a boost voltage sense circuit (not illustrated), which generates the enable signal EN_{SAMP} based on comparison of the boost voltage V_{BST} with the judgement voltage. The comparison here may be given hysteresis.

As will be understood from the description above, in the ith unit period, which correspond to the high-level period of the address selection signal SEL_{ADD}[i], of the gate voltages V_{OTPG}[1] to V_{OTPG}[N], only the gate voltage V_{OTPG}[i] is substantially equal to the boost voltage V_{BST}, the other gate voltages being 0 V. As shown in FIG. 8, in the high-level period of the clock signal CLK_N within the ith unit period, the gate voltage V_{OTPG}[i] is equal to the reference voltage V_{REG}, and in the low-level period of the clock signal CLK_N within the ith unit period, the gate voltage V_{OTPG}[i] is higher than the reference voltage V_{REG}. Likewise, in the high-level period of the clock signal CLK_N within the (i+1)th unit period, the gate voltage V_{OTPG}[i+1] is equal to the reference voltage V_{REG}, and in the low-level period of the clock signal CLK_N within the (i+1)th unit period, the gate voltage V_{OTPG}+11 is higher than the reference voltage V_{REG}. In any other unit period, similar control takes place. In the following description, the high- and low-level periods of the clock signal CLK_N within the ith unit period will be identified specifically by the symbols “Pa” and “Pb” respectively.

[Read Operation]

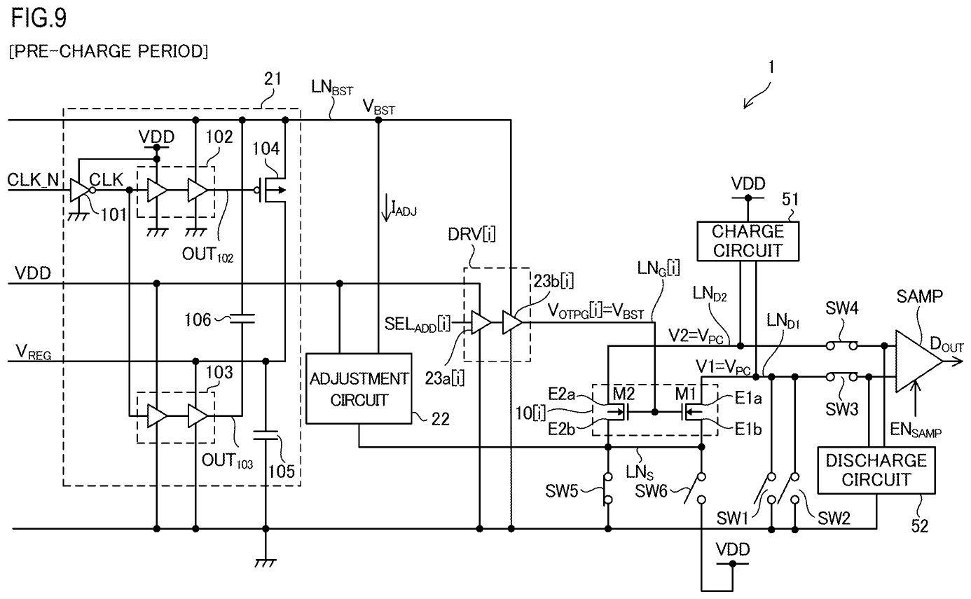

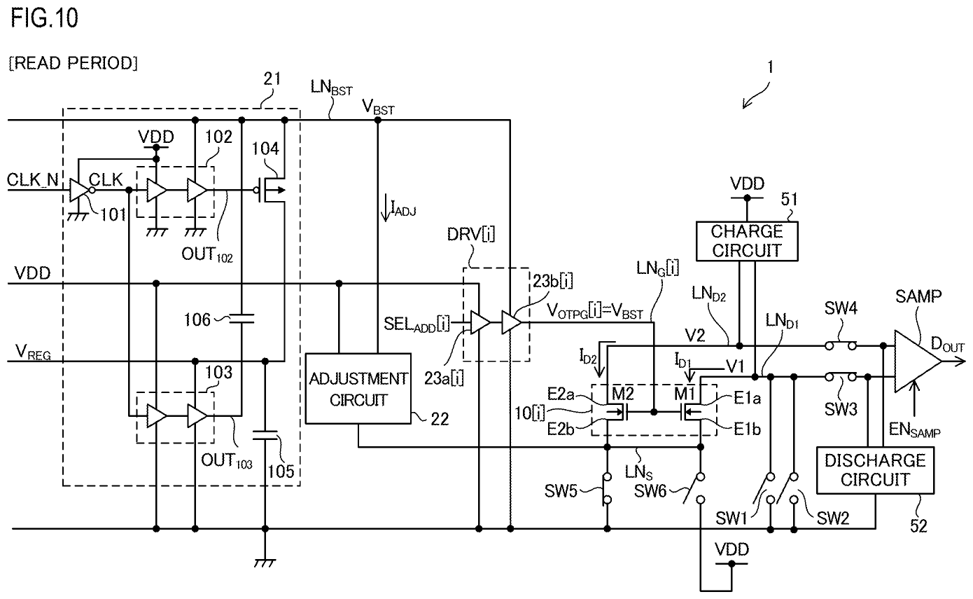

While similar to the read operation described previously with reference to FIGS. 2 and 3, the read operation performed with respect to the memory cell 10[i] will be described with reference to FIGS. 9 and 10. In any period (including the pre-charge and read periods) other than the program period in which the program operation is performed, the switches SW1, SW2, and SW6 are kept off and the switches SW3 to SW5 are kept on. Accordingly, in the pre-charge and read periods, the voltage on the source line LN_{S} is set to 0 V, so that the electrodes E1a and E2a function as the drains and the electrodes E1b and E2b as the sources. The pre-charge and read periods with respect to the memory cell 10[i] are set to occur within the ith unit period. Specifically, for example, the periods Pa and Pb shown in FIG. 8 can be set as the pre-charge and read periods, respectively, with respect to the memory cell 10[i].

In the pre-charge period, the charge circuit 51 feeds a positive charge to each of the drain lines LN_{D1} and LN_{D2}, so that as shown in FIG. 9 a common pre-charge voltage V_{PC} is set for the voltages V1 and V2 on the drain lines LN_{D1} and LN_{D2}. In a case where the pre-charge period with respect to the memory cell 10[i] is the period Pa, V_{OTPG}[i]=V_{BST}=V_{REG}>0, and thus while in that pre-charge period a comparable drain current can pass through at least one of the transistors M1 and M2, in the pre-charge period the voltages V1 and V2 are kept at the pre-charge voltage V_{PC}. Incidentally, in the pre-charge period and the read period, the discharge circuit 52 does not function significantly (the discharge circuit 52 can be thought of as non-existent).

After the pre-charge period, when the period Pb shown in FIG. 8 starts, the read period for the memory cell 10[i] starts. The gate voltage V_{OTPG}[i] in the period Pb corresponds to the read voltage V_{RD} (see FIG. 3) mentioned previously. The gate voltage V_{OTPG}[i] in the period Pb is higher than at least one of the gate threshold voltages of the transistors M1 and M2. In the read period, the input impedances of the circuits 51 and 52 and the sense amplifier SAMP as seen from the drain lines LN_{D1} and LN_{D2} are set to be significantly high. As a result, in the read period for the memory cell 10[i], only the passage of a drain current I_{D1} through the transistor M1 in the memory cell 10[i] causes the voltage V1 on the line LN_{D1} to fall, and only the passage of a drain current I_{D2} through the transistor M2 in the memory cell 10[i] causes the voltage V2 on the line LN_{D2} to fall (see FIG. 10).

The operation of the sense amplifier SAMP based on the drain currents I_{D1} and I_{D2} in the memory cell 10[i] is similar to the operation, described previously with reference to FIG. 3 etc., of the signal output circuit 30 based on the drain currents I_{D1} and I_{D2} in the memory cell 10. Accordingly, in the read operation with respect to the memory cell 10[i], the sense amplifier SAMP senses, based on the voltages at its first and second input terminals (hence based on the voltages V1 and V2), the magnitude relationship between the drain currents I_{D1} and I_{D2} to output, if I_{D2}>I_{D1}, a signal D_{OUT} associated with a first value (in other words, a signal D_{OUT} representing the first value) and, if I_{D2}<ID₁, a signal D_{OUT} associated with a second value (in other words, a signal D_{OUT} representing the second value). Note that it is only in the high-level period of the enable signal EN_{SAMP} that a significant signal D_{OUT} is output. As mentioned previously, a low-level signal D_{OUT} represents the first value (0) and a high-level signal D_{OUT} represents the second value (2). Then, for example by identifying whichever of the voltages V1 and V2 becomes equal to or lower than a predetermined voltage first after the start of the read period, the sense amplifier SAMP can determine the level of the signal D_{OUT}.

[Program Operation]

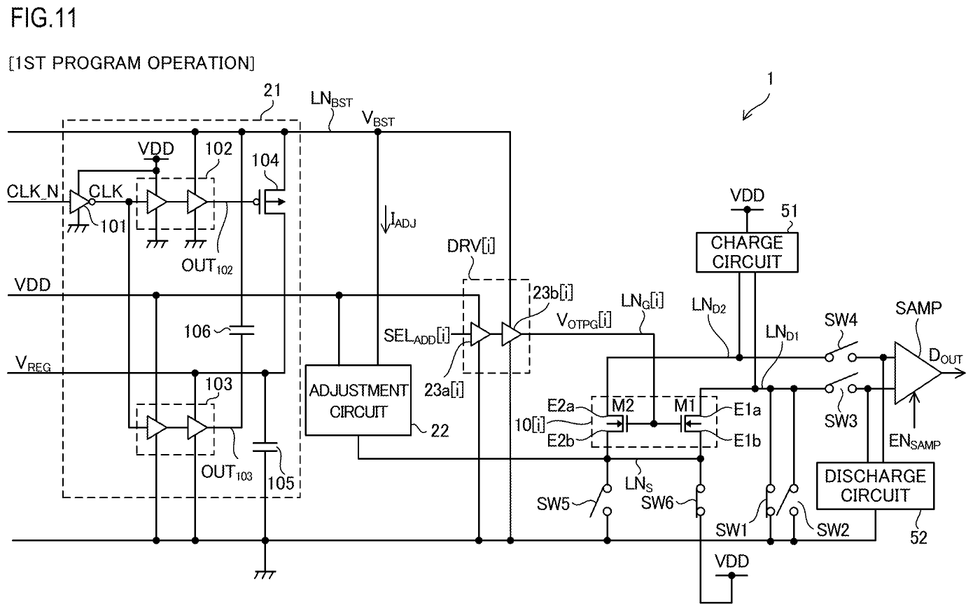

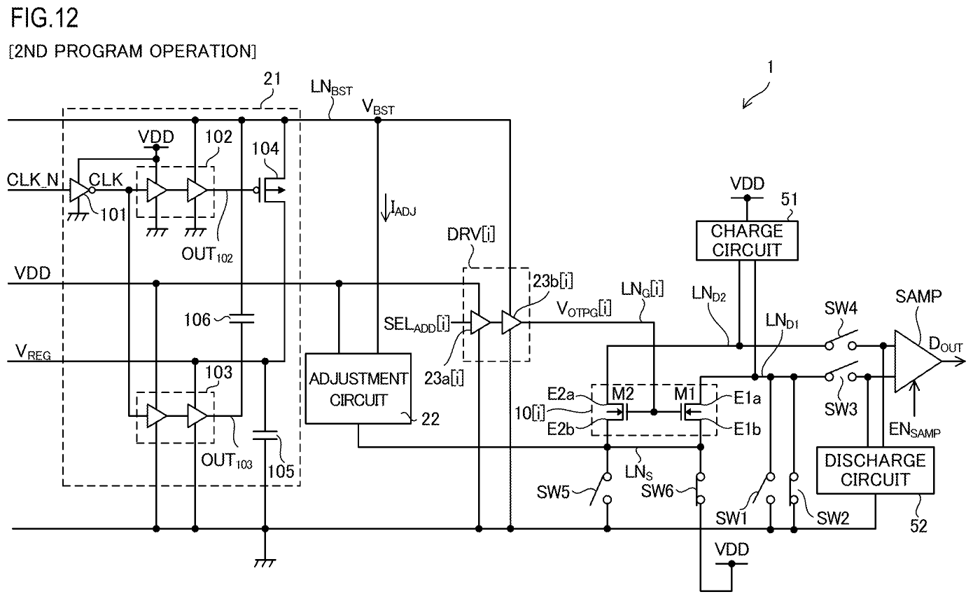

While similar to the program operation described previously with reference to FIGS. 5A and 5B, the program operation performed with respect to the memory cell 10[i] will be described with reference to FIGS. 11 and 12. As mentioned previously, the program operation can be a first program operation or a second program operation.

In both the first and second program operations, the switches SW3 to SW5 are off and the switch SW6 is on. As a result, the supply voltage VDD is fed to the electrodes E1b and E2b of the transistors M1 and M2, and these electrodes function as the drains. Here, the supply voltage VDD functions as the voltage V_{PRG1} shown in FIGS. 5A and 5B. It is assumed that the adjustment circuit 22 is a circuit that functions effectively in the read operation and thus that it does not draw the adjustment current I_{ADJ} during the execution of the program operation. Moreover, when the first or second program operation is executed with respect to the memory cell 10[i], the address selection signal SEL_{ADD}[i] is kept at high level in the program period.

In the program period of the first program operation, as shown in FIG. 11, the switch SW1 is kept on and the switch SW2 is kept off, so that a current passes from the line LN_{S} via the electrodes E1b and E1a and the switch SW1 to the ground. While this current is passing, hot carriers are injected into the transistor M1 and the characteristics of the transistor M1 change such that the gate threshold voltage of the transistor M1 increases. The program period is maintained for a length of time required for a sufficient increase in the gate threshold voltage of the transistor M1, and then the first program operation ends. In the program period of the first program operation, the line LN_{D2} is in a high-impedance state, and no current passes between the electrodes E2a and E2b.

On the other hand, in the program period of the second program operation, as shown in FIG. 12, the switch SW1 is kept off and the switch SW2 is kept on, so that a current passes from the line LN_{S} via the electrodes E2b and E2a and the switch SW2 to the ground. While this current is passing, hot carriers are injected into the transistor M2 and the characteristics of the transistor M2 change such that the gate threshold voltage of the transistor M2 increases. The program period is maintained for a length of time required for a sufficient increase in the gate threshold voltage of the transistor M2, and then the second program operation ends. In the program period of the second program operation, the line LN_{D1} is in a high-impedance state, and no current passes between the electrodes E1a and E1b.

When after the first program operation is executed with respect to the memory cell 10[i] the read operation is performed with respect to the memory cell 10[i], the increase in the gate threshold voltage of the transistor M1 during the first program operation results in I_{D2}>ID₁ in the read operation, and consequently a signal D_{OUT} representing the first value (0) is output. That is, the data of “0” stored in the memory cell 10[i] is read out. When after the second program operation is executed with respect to the memory cell 10[i] the read operation is performed with respect to the memory cell 10[i], the increase in the gate threshold voltage of the transistor M2 during the second program operation results in I_{D2}<ID₁ in the read operation, and consequently a signal D_{OUT} representing the second value (1) is output. That is, the data of “1” stored in the memory cell 10[i] is read out.

[Adjustment Circuit]

FIG. 13 shows a configuration example of the adjustment circuit 22. The adjustment circuit 22 in FIG. 13 includes an adjustment transistor M_{ADJ}, transistors 121 to 126, and transistors 131 to 134. The adjustment transistor M_{ADJ} and the transistors 123, 124, 131, and 132 are configured as N-channel MOSFETs, and the transistors 121, 122, 125, 126, 133, and 134 are configured as P-channel MOSFETs.

The adjustment transistor M_{ADJ} is configured with the same device as that used in a memory element. That is, the adjustment transistor M_{ADJ} is configured as a MOSFET with the same structure as the MOSFET constituting the transistor M1 or the MOSFET constituting the transistor M2.

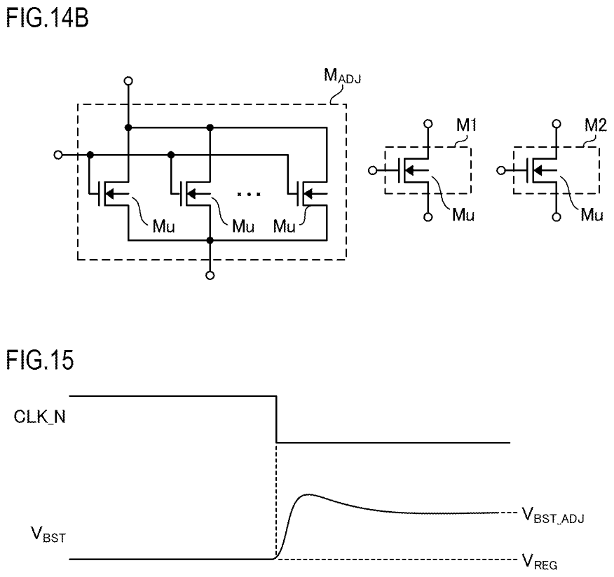

With attention paid to one transistor M1 and one transistor M2, a first to a third unit transistor Mu all with the same structure can be formed on a semiconductor substrate on which the storage circuit 1 is to be integrated and, as shown in FIG. 14A, the first and second unit transistors Mu can be used as the transistors M1 and M2 respectively and the third unit transistor Mu as the adjustment transistor M_{ADJ}. Instead, a first to a kth unit transistor Mu (where k is any integer of four or more) all with the same structure can be formed on a semiconductor substrate on which the storage circuit 1 is to be integrated and, as shown in FIG. 14B, the first and second unit transistors Mu can be used as the transistors M1 and M2 respectively and the parallel circuit of the third to kth unit transistors Mu as the adjustment transistor M_{ADJ}.

Thus, after the first program operation (hence with no hot carriers injected into the transistor M2), when a common gate-source voltage is fed to the transistors M2 and M_{ADJ}, a drain current commensurate with the drain current in the adjustment transistor M_{ADJ} passes through the transistor M2. Likewise, after the second program operation (hence with no hot carriers injected into the transistor M1), when a common gate-source voltage is fed to the transistors M1 and M_{ADJ}, a drain current commensurate with the drain current in the adjustment transistor M_{ADJ} passes through the transistor M1.

A description will now be given of the interconnections among the circuit elements in the adjustment circuit 22. The line to which the supply voltage VDD is applied will be referred to also as the supply voltage line LN_{VDD}. The sources of the transistors 121, 122, 125, 126, 133, and 134 are connected to the supply voltage line LN_{VDD}. The gate and drain of the transistor 121, the gate of the transistor 122, and the drains of the transistors 126, 133, and 131 are connected together to a node ND1. The source of the transistor 131 is connected to the drain of the adjustment transistor M_{ADJ}. Of the adjustment transistor M_{ADJ}, the gate is connected to the boost line LN_{BST} and the source is connected to the line LN_{S}. The drain of the transistor 122 is connected to the drain and gate of the transistor 123 and to the gate of the transistor 124. The sources of the transistors 123 and 124 are connected to the line LN_{S}. The drain of the transistor 124 is connected to the source of the transistor 132, and the drain of the transistor 132 is connected to the boost line LN_{BST}. The drain and gate of the transistor 125, the gate of the transistor 126, and the drain of the transistor 134 are connected together.

A description will now be given of the input signals and input voltages to the adjustment circuit 22 in FIG. 13 as well as the operation of the adjustment circuit 22 in FIG. 13. The adjustment current I_{ADJ} mentioned previously (see FIGS. 6 and 7) passes through the channels (between drain and source) of the transistors 132 and 124. The gates of the transistors 132 to 134 are each fed with an enable signal EN_{ADJ}. The enable signal EN_{ADJ} is output from the control circuit 40. The enable signal EN_{ADJ} has, when at high level, the potential of the supply voltage VDD and, when at low level, the ground potential. The control circuit 40 can keep the enable signal EN_{ADJ} at low level in the program period and at high level in any other period (including the pre-charge and read periods). The adjustment circuit 22 functions effectively only in the high-level period of the enable signal EN_{ADJ}. That is, in the high-level period of the enable signal EN_{ADJ}, the transistor 132 is in a state where it permits a non-zero adjustment current I_{ADJ} to pass across its channel and the transistors 133 and 134, which function as switches, are both off. In the low-level period of the enable signal EN_{ADJ}, the transistor 132 is off and thus, irrespective of the boost voltage V_{BST}, no adjustment current I_{ADJ} passes through it and no constant current I_{CC}, of which a description will be given later, is produced. In the following description, unless otherwise stated, the enable signal EN_{ADJ} is assumed to be at high level.

The gate of the transistor 131 is fed with a predetermined positive voltage Vp1. If, with the gate voltage of the adjustment transistor M_{ADJ} sufficiently high, an excessive drain voltage is applied to the adjustment transistor M_{ADJ}, hot carriers are produced in the adjustment transistor M_{ADJ} and the characteristics of the adjustment transistor M_{ADJ} change. To prevent an excessive drain voltage from being applied to the adjustment transistor M_{ADJ}, the transistor 131 is inserted between the node ND1 and the adjustment transistor M_{ADJ}. The gates of the transistors 125 and 126 and the drains of the transistors 125 and 134 are fed with a predetermined positive voltage Vp2 lower than the supply voltage VDD (in the low-level period of the enable signal EN_{ADJ}, the voltage Vp2 may be suspended from being output).

The transistors 125 and 126 form a current mirror circuit, and this current mirror circuit functions as a constant current circuit CC. That is, a constant current I_{CC} is output from the drain of the transistor 126 toward the node ND1. The voltage Vp2 is given such a value that the constant current I_{CC} has a predetermined current value (e.g., 10 μA). The node ND1 is connected via the transistor 131 to the drain of the adjustment transistor M_{ADJ}, and thus the constant current circuit CC can be understood to output the constant current I_{CC} toward the drain of the adjustment transistor M_{ADJ}.

The transistors 121 and 122 form a current mirror circuit CM1. The transistors 123 and 124 form a current mirror circuit CM2. The drain current in the transistor 121 will be referred to as the current Ia, and the drain current in the transistor 122 as the current Ib. The drain current in the transistor 124 is the adjustment current I_{ADJ}. Thus the current Ia, the current Ib, and the adjustment current I_{ADJ} are in a mutually proportional relationship. The current ratio between the currents Ia and Ib may be one or other than one. The current ratio between the currents Ib and I_{ADJ} may be one or other than one. The line that connects together the drains of the transistors 122 and 123 will be referred to specifically as the line LN11.

The current mirror circuit CM1, while outputting the current Ia toward the drain of the adjustment transistor M_{ADJ}, produces in the line LN11 the current Ib proportional to the current Ia. The current mirror circuit CM2 produces the adjustment current I_{ADJ} proportional to the current Ib passing across the line LN11 to draw the adjustment current I_{ADJ} from the boost line LN_{BST}.

The drain current in the adjustment transistor M_{ADJ} is the sum of the current Ia (first current) and the constant current I_{CC} (second current). In the adjustment transistor M_{ADJ} passes a drain current commensurate with the boost voltage V_{BST}. As the boost voltage V_{BST} increases, the drain current through the adjustment transistor M_{ADJ} increases, and as the drain current through the adjustment transistor M_{ADJ} increases, the currents Ia and Ib increase, and so does the adjustment current I_{ADJ}.

The operation of the adjustment circuit 22 will now be described, starting in a state where the boost voltage V_{BST} is sufficiently high. With the boost voltage V_{BST} sufficiently high, as the drain current in the adjustment transistor M_{ADJ} increases, the current Ia too increases, with the result that the currents Ib and I_{ADJ} increase. The increased adjustment current I_{ADJ} results in a reduced boost voltage V_{BST}. As the adjustment current I_{ADJ} is drawn from the boost line LN_{BST} and hence the boost voltage V_{BST} decreases, the drain current in the adjustment transistor M_{ADJ} decreases and, while the potential at the node ND1 rises, the current Ia (first current) decreases so much as the drain current in the adjustment transistor M_{ADJ} decreases. As a result, the adjustment current I_{ADJ} too decreases. Eventually, the currents Ia and Ib and the current I_{ADJ} become zero, only the constant current I_{CC} left passing in the adjustment transistor M_{ADJ}.

In FIG. 8, in synchronism with the clock signal CLK_N the boost voltage V_{BST} varies with a substantially rectangular waveform; in reality, as shown in FIG. 15, in synchronism with a down edge in the clock signal CLK_N the boost voltage V_{BST} rises from the reference voltage V_{REG} to a voltage higher than a voltage V_{BST}_ADJ and then, through the drawing of the adjustment current I_{ADJ}, the boost voltage V_{BST} settles at the voltage V_{BST}_ADJ. A state where V_{BST}=V_{BST}_ADJ corresponds to a state where the drain current in the adjustment transistor M_{ADJ} is equal to the constant current I_{CC} (i.e., a state where I_{ADJ}=0). The voltage V_{BST}_ADJ corresponds to the boost voltage V_{BST} as it is after adjustment by the adjustment circuit 22.

As described above, in this embodiment, the adjustment current I_{ADJ} commensurate with the boost voltage V_{BST} is drawn from the boost line LN_{BST} to adjust the boost voltage V_{BST} and, in the read operation, the adjusted boost voltage V_{BST} is fed as the read voltage V_{RD} to each of the gates of the transistors M1 and M2. With attention paid to the memory cell 10[i], in a period Pb (see FIG. 8) corresponding to the read period with respect to the memory cell 10[i], the boost voltage V_{BST} raised to be higher than the reference voltage V_{REG} is adjusted by the adjustment circuit 22, and the adjusted boost voltage V_{BST} is fed as the gate voltage V_{OTPG}[i] and also as the read voltage V_{RD} to each of the gates of the transistors M1 and M2 in the memory cell 10[i]. In this way, the drain current ID₁ or I_{D2} in the read operation is optimized, and this achieves power saving and hence size reduction in a peripheral circuit and improved characteristics in the non-volatile memory.

In particular, the adjustment transistor M_{ADJ} configured with the same device as the one constituting the transistor M1 or M2 is provided in the adjustment circuit 22, and the boost voltage V_{BST} is adjusted such that, with the boost voltage V_{BST} fed between the gate and source of the adjustment transistor M_{ADJ}, the constant current I_{CC} passes through the adjustment transistor M_{ADJ}. This optimizes the drain current ID₁ or I_{D2} in the read operation in the face of element-to-element variation and temperature variation. Specifically, for example, in a case where the configuration in FIG. 14A is employed, in the transistor M1 or M2 that receives at its gate the adjusted boost voltage V_{BST} passes a drain current of the same magnitude as the constant current I_{CC} (with an error ignored). That is, the magnitude of the drain current I_{D1} or I_{D2} in the read operation can be kept equal to that of the constant current I_{CC} all the time in the face of element-to-element variation and temperature variation. Thus the only requirement is to set the value of the constant current I_{CC} at the optimal value for the drain current I_{D1} or I_{D2} in the read operation. A similar description applies also in a case where the configuration in FIG. 14B is employed. In a case where the configuration in FIG. 14B is employed, however, the value of the constant current I_{CC} is set with consideration given to the constant current I_{CC} passing through the parallel circuit of a plurality of unit transistors Mu. Employing the configuration in FIG. 14B, compared with the configuration in FIG. 14A, permits the boost voltage V_{BST} to more quickly settle at the voltage V_{BST_ADJ} in the period Pb.

### Second Embodiment

A second embodiment of the present disclosure will be described. The second embodiment is an embodiment based on the first embodiment. For any features of the second embodiment that are not specifically described, unless inconsistent, the corresponding part of the description of the first embodiment applies to the second embodiment as well. In interpreting the description of the second embodiment, for any features that contradict between the first and second embodiments, the description given in connection with the second embodiment can prevail.

In the second embodiment, when the memory cell 10 or 10[i] is in the initial state (in a state where no program operation has ever been performed at all), an initial value of “0” is stored in the memory cell 10 or 10[i]. To achieve this, in the second embodiment, the transistors M1 and M2 are given different structures.

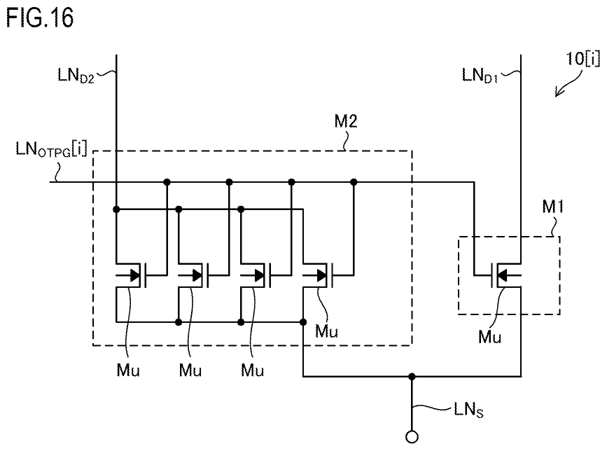

A configuration example of the memory cell 10[i] according to the second embodiment is shown in FIG. 16. In the memory cell 10[i], the transistor M1 is configured as a single unit transistor Mu, and the transistor M2 is configured as a parallel circuit of n unit transistors Mu. Here, n is any integer of two or more. FIG. 16 shows a configuration example where n=4. A total of (n+1) unit transistors Mu included in the memory cell 10[i] in FIG. 16 are N-channel MOSFETs all with the same structure. In a case where n=4, if the five unit transistors Mu included in the memory cell 10[i] are referred to as the first to fifth unit transistors Mu, the transistor M1 is the first unit transistor Mu in its own, and the transistor M2 is configured as a parallel circuit of the second to fifth unit transistors Mu. More specifically, the gates of the second to fifth unit transistors Mu are connected together to serve as the gate of the transistor M2, the drains of the second to fifth unit transistors Mu are connected together to serve as the drain of the transistor M2, and the sources of the second to fifth unit transistors Mu are connected together to serve as the source of the transistor M2.

With this configuration, in the memory cell 10[i] in its initial state (i.e., in a state where no program operation has ever been performed at all), when the read operation is performed, the drain current I_{D2} in the transistor M2 is n times the drain current I_{D1} in the transistor M1 (with an error ignored) and, through the read operation, a value of “0” is read out from the memory cell 10[i] (i.e., the sense amplifier SAMP outputs a signal D_{OUT} representing “0”).

In the second embodiment, the first program operation (see FIG. 11) is not performed as the program operation; the program operation is limited to the second program operation (see FIG. 12). Accordingly, the switch SW1 is omitted from the storage circuit 1, or is fixed to be off.

In the storage circuit 1 according to the second embodiment, when the second program operation is executed with the switches in the states shown in FIG. 12, a current passes from the line LN_{S} via the electrodes E2b and E2a and the switch SW2 to the ground. While this current is passing, hot carriers are injected into the transistor M2 and the characteristics of the transistor M2 (the characteristics of the individual unit transistors Mu constituting the transistor M2) change, with the result that the gate threshold voltage of the transistor M2 increases. The program period is maintained for a length of time required for a sufficient increase in the gate threshold voltage of the transistor M2, and then the second program operation ends. In the program period of the second program operation, the line LN_{D1} is in a high-impedance state, and no current passes between the electrodes E1a and E1b. When after the second program operation is executed with respect to the memory cell 10[i] the read operation is performed with respect to the memory cell 10[i], the increase in the gate threshold voltage of the transistor M2 during the second program operation results in I_{D2}<I_{D1} in the read operation, and consequently a signal D_{OUT} representing the second value (1) is output. That is, the data of “1” stored in the memory cell 10[i] is read out.

The adjustment circuit 22 in the second embodiment has a configuration similar to that in the first embodiment: the adjustment transistor M_{ADJ} is configured as a single unit transistor Mu or as a parallel circuit of a plurality of unit transistors Mu. Thus, the second embodiment provides workings and benefits similar to those the first embodiment provides.

As an alternative to configuring the transistor M2 as a parallel circuit of n unit transistors Mu, the following configuration is possible. For example, while the transistor M1 is configured with a unit transistor Mu, the MOSFET serving as the transistor M2 may be given a larger gate width than that of the MOSFET serving as the transistor M1 (i.e., the MOSFET serving as the unit transistor Mu) such that, in the read operation in the initial state, I_{D2}>I_{D1}.

### Modifications

To follow is a description of modified examples, application examples, and the like that are applicable to the first or second embodiment.

In the examples of operation described above, it is assumed that the first value is “0” and the second value is “1”. In practice, the first and second values may be any values so long as they have different values. The circuit configuration may be modified such that the signal D_{OUT} associated with the first value is a high-level signal and that the signal D_{OUT} associated with the second value is a low-level signal.

A non-volatile memory (storage circuit 1) according to the present disclosure can be incorporated in any circuit or device that carries out a predetermined functional operation. When the circuit or device incorporating the non-volatile memory starts to be fed with a supply voltage and starts up, it reads data stored in the non-volatile memory by a read operation and carries out the predetermined functional operation according to the read data. For example, a non-volatile memory (storage circuit 1) can be incorporated in an amplifier circuit (not illustrated) of which the gain can be varied according to trimming data, and the gain of the amplifier circuit can be adjusted optimally by feeding the amplifier circuit with, as trimming data, one or more sets of data stored in the non-volatile memory. A non-volatile memory according to the present disclosure can be incorporated in semiconductor integrated circuits for a variety of uses, such as semiconductor integrated circuits for DC-DC converters and semiconductor integrated circuits for motor drivers. The amplifier circuit just mentioned is an example of a circuit provided in such semiconductor integrated circuits.

The channel type of any of the FETs (field-effect transistors) presented in the embodiments is merely illustrative: any circuit including FETs may be modified such that any N-channel FET is replaced with a P-channel FET or that any P-channel FET is replaced with an N-channel FET.

Unless any inconvenience arises, any of the transistors mentioned above may be of any type. For example, unless any inconvenience arises, any transistor mentioned above as a MOSFET may be replaced with a junction FET, an IGBT (insulated-gate bipolar transistor), or a bipolar transistor. Any transistor has a first electrode, a second electrode, and a control electrode. In an FET, of the first and second electrodes one is the drain and the other is the source, and the control electrode is the gate. In an IGBT, of the first and second electrodes one is the collector and the other is the emitter, and the control electrode is the gate. In a bipolar transistor that is not classified as an IGBT, of the first and second electrodes one is the collector and the other is the emitter, and the control electrode is the base.

Embodiments of the present disclosure can be modified in many ways as necessary without departure from the scope of the technical concepts defined in the appended claims. The embodiments described herein are merely examples of how the present disclosure can be implemented, and what is meant by any of the terms used to describe the present disclosure and its constituent elements is not limited to that mentioned in connection with the embodiments. The specific values mentioned in the above description are merely illustrative and needless to say can be modified to different values.

<< Notes>>

To follow is a study on the technical ideals that underlie the embodiments described above.

According to one aspect of what is disclosed herein, a non-volatile memory includes: a memory cell having a first transistor and a second transistor; a drive circuit configured to feed a read voltage to the gates of the first and second transistors; and a signal output circuit configured to output, in a read operation in which the read voltage is fed, a signal associated with a first value or a signal associated with a second value based on the drain currents in the first and second transistors. The drive circuit includes: a boost circuit configured to generate a boost voltage on a boost line by boosting a predetermined reference voltage; and an adjustment circuit configured to adjust the boost voltage by drawing from the boost line an adjustment current commensurate with the boost voltage. The drive circuit is configured to feed, in the read operation, the adjusted boost voltage as the read voltage to the gates of the first and second transistors. (A first configuration.)

In the non-volatile memory of the first configuration described above, the adjustment circuit may include an adjustment transistor having a gate connected to the boost line, a drain current commensurate with the boost voltage may pass in the adjustment transistor, and the adjustment current may have a magnitude commensurate with the drain current in the adjustment transistor. (A second configuration.)

In the non-volatile memory of the second configuration described above, as the boost voltage increases, the drain current in the adjustment transistor may increase, and as the drain current in the adjustment transistor increases, the adjustment current may increase. (A third configuration.)

In the non-volatile memory of the third configuration described above, the adjustment circuit may be configured to feed the sum of a first current proportional to the adjustment current and a predetermined second current to the drain of the adjustment transistor. As the adjustment current is drawn from the boost line, the boost voltage may decrease, and when as a result the drain current in the adjustment transistor decreases, the first current may decrease as much as the drain current decreases and consequently the adjustment current decreases. (A fourth configuration.)

In the non-volatile memory of the fourth configuration described above, the adjustment circuit may include: a first current mirror circuit configured to output the first current toward the drain of the adjustment transistor and to generate a current proportional to the first current on a predetermined line; a second current mirror circuit configured to generate as the adjustment current a current proportional to the current passing in the predetermined line, thereby to draw the adjustment current from the boost line; and a constant current circuit configured to output the second current as a constant current toward the drain of the adjustment transistor. (A fifth configuration.)

In the non-volatile memory of any of the second to fifth configurations described above, the adjustment transistor may be configured as a MOSFET with the same structure as the MOSFET constituting the first or second transistor. (A sixth configuration.)

In the non-volatile memory of any of the first to sixth configurations described above, the boost circuit may be configured as a charge pump circuit configured to boost the reference voltage with a capacitor and a switch. (A seventh configuration.)

In the non-volatile memory of any of the first to seventh configurations described above, the signal output circuit may be configured to output, in the read operation, the signal associated with the first value if the drain current in the second transistor is higher than the drain current in the first transistor and the signal associated with the second value if the drain current in the first transistor is higher than the drain current in the second transistor. (An eighth configuration.)

In the non-volatile memory of the eighth configuration described above, the non-volatile memory may be configured to be capable of executing a program operation to inject hot carriers into one of the first and second transistors to increase the gate threshold voltage of the one of the first and second transistors. In the read operation executed after the program operation, as a result of the increase in the gate threshold voltage of the one of the first and second transistors having hot carriers injected thereinto, the drain current in another of the first and second transistors may be higher than the drain current in the one of the first and second transistors. (A ninth configuration.)

In the non-volatile memory of the eighth configuration described above, the non-volatile memory may be configured to be capable of executing a program operation to inject hot carriers into the second transistor to increase a gate threshold voltage of the second transistor. In the read operation executed before the program operation, the drain current in the second transistor may be higher than the drain current in first transistor. In the read operation executed after the program operation, as a result of the increase in the gate threshold voltage of the second transistor during the program operation, the drain current in the first transistor may be higher than the drain current in the second transistor. (A tenth configuration.)

According to another aspect of what is disclosed herein, a non-volatile memory includes: a memory cell having a first transistor and a second transistor; a drive circuit configured to be capable of feeding a read voltage to the gates of the first and second transistors; and a signal output circuit configured to be capable of outputting, in a read operation in which the read voltage is fed, a signal associated with a first value or a signal associated with a second value based on the drain currents in the first and second transistors. The drive circuit includes: a boost circuit configured to be capable of generating a boost voltage on a boost line by boosting a predetermined reference voltage; and an adjustment circuit configured to be capable of adjusting the boost voltage by drawing from the boost line an adjustment current commensurate with the boost voltage. When the read operation is performed, in the read operation, the drive circuit feeds the adjusted boost voltage as the read voltage to the gates of the first and second transistors. (An eleventh configuration.)

1. A non-volatile memory, comprising:
a memory cell having a first transistor and a second transistor;
a drive circuit configured to feed a read voltage to gates of the first and second transistors; and
a signal output circuit configured to output, in a read operation in which the read voltage is fed, a signal associated with a first value or a signal associated with a second value based on drain currents in the first and second transistors,
wherein
the drive circuit includes:
a boost circuit configured to generate a boost voltage on a boost line by boosting a predetermined reference voltage; and
an adjustment circuit configured to adjust the boost voltage by drawing from the boost line an adjustment current commensurate with the boost voltage, and
the drive circuit is configured to feed, in the read operation, the adjusted boost voltage as the read voltage to the gates of the first and second transistors.

2. The non-volatile memory according to claim 1, wherein
the adjustment circuit includes an adjustment transistor having a gate connected to the boost line,
a drain current commensurate with the boost voltage passes in the adjustment transistor, and
the adjustment current has a magnitude commensurate with the drain current in the adjustment transistor.

3. The non-volatile memory according to claim 2, wherein
as the boost voltage increases, the drain current in the adjustment transistor increases, and
as the drain current in the adjustment transistor increases, the adjustment current increases.

4. The non-volatile memory according to claim 3, wherein
the adjustment circuit is configured to feed a sum of a first current proportional to the adjustment current and a predetermined second current to a drain of the adjustment transistor, and
as the adjustment current is drawn from the boost line, the boost voltage decreases, and when as a result the drain current in the adjustment transistor decreases, the first current decreases as much as the drain current decreases and consequently the adjustment current decreases.

5. The non-volatile memory according to claim 4, wherein
the adjustment circuit includes:
a first current mirror circuit configured
to output the first current toward the drain of the adjustment transistor and
to generate a current proportional to the first current on a predetermined line;
a second current mirror circuit configured
to generate as the adjustment current a current proportional to a current passing in the predetermined line thereby
to draw the adjustment current from the boost line; and
a constant current circuit configured to output the second current as a constant current toward the drain of the adjustment transistor.

6. The non-volatile memory according to claim 1, wherein
the adjustment transistor is configured as a MOSFET with a same structure as a MOSFET constituting the first or second transistor.

7. The non-volatile memory according to claim 1, wherein
the boost circuit is configured as a charge pump circuit configured to boost the reference voltage with a capacitor and a switch.

8. The non-volatile memory according to claim 1, wherein
the signal output circuit is configured to output, in the read operation,
the signal associated with the first value if a drain current in the second transistor is higher than a drain current in the first transistor and
the signal associated with the second value if the drain current in the first transistor is higher than the drain current in the second transistor.

9. The non-volatile memory according to claim 8, wherein
the non-volatile memory is configured to be capable of executing a program operation to inject hot carriers into one of the first and second transistors to increase a gate threshold voltage of the one of the first and second transistors, and
in the read operation executed after the program operation, as a result of an increase in the gate threshold voltage of the one of the first and second transistors having hot carriers injected thereinto, the drain current in another of the first and second transistors is higher than the drain current in the one of the first and second transistors.

10. The non-volatile memory according to claim 8, wherein
the non-volatile memory is configured to be capable of executing a program operation to inject hot carriers into the second transistor to increase a gate threshold voltage of the second transistor,
in the read operation executed before the program operation, the drain current in the second transistor is higher than the drain current in first transistor, and
in the read operation executed after the program operation, as a result of an increase in the gate threshold voltage of the second transistor during the program operation, the drain current in the first transistor is higher than the drain current in the second transistor.

11. A non-volatile memory, comprising:
a memory cell having a first transistor and a second transistor;
a drive circuit configured to be capable of feeding a read voltage to gates of the first and second transistors; and
a signal output circuit configured to be capable of outputting, in a read operation in which the read voltage is fed, a signal associated with a first value or a signal associated with a second value based on drain currents in the first and second transistors,
wherein
the drive circuit includes:
a boost circuit configured to be capable of generating a boost voltage on a boost line by boosting a predetermined reference voltage; and
an adjustment circuit configured to be capable of adjusting the boost voltage by drawing from the boost line an adjustment current commensurate with the boost voltage, and
when the read operation is performed, in the read operation, the drive circuit feeds the adjusted boost voltage as the read voltage to the gates of the first and second transistors.
